(19) United States
(12) Patent Application Publication
(10) Pub. No.: US 2013/0265102 A1
(43) Pub. Date: Oct. 10, 2013

(54) SEMICONDUCTOR STRUCTURE AND METHOD FOR MANUFACTURING THE SAME

(71) Applicants: Chen-Yuan Lin, Taitung City (TW); Cheng-Chi Lin, Toucheng Township (TW); Ching-Lin Chan, Huwei Township (TW); Shih-Chin Lien, New Taipei City (TW); Shyi-Yuan Wu, Hsinchu City (TW)

(72) Inventors: Chen-Yuan Lin, Taitung City (TW); Cheng-Chi Lin, Toucheng Township (TW); Ching-Lin Chan, Huwei Township (TW); Shih-Chin Lien, New Taipei City (TW); Shyi-Yuan Wu, Hsinchu City (TW)

(73) Assignee: MACRONIX INTERNATIONAL CO., LTD., Hsinchu (TW)

(21) Appl. No.: 13/442,340

(22) Filed: Apr. 9, 2012

(51) Int. Cl. H01L 29/808; G11C 5/14; H01L 21/337

(52) U.S. Cl. 327/530; 257/256; 438/186; 257/E29.312; 257/E21.445

(57) ABSTRACT

A semiconductor structure and method for manufacturing the same are provided. The semiconductor structure includes a substrate having a first conductive type; a deep well having a second conductive type formed in the substrate and extending down from a surface of the substrate; a first well having the first conductive type formed in the deep well and extending down from the surface of the substrate; and a second well having the second conductive type formed in the deep well and extending down from the surface of the substrate, and the second well adjacent to the first well. The first well includes a block region and plural finger regions joined to one side of the block region, while the second well includes plural channel regions interlaced with the finger regions to separate the finger regions.

### BACKGROUND

1. Technical Field

The disclosure relates in general to a semiconductor structure and a method for manufacturing the same, and more particularly to a high-voltage (HV) semiconductor structure and method for manufacturing the same.

2. Description of the Related Art

In the semiconductor technology, the feature size has been reduced. In the meantime, the rate, the efficiency, the density and the cost per integrated circuit unit have been improved. For a semiconductor device operated at high voltage or ultra high voltage, the pinch-off voltage of the semiconductor device is controlled by the channel width, and the pinch capability is influenced by channel length. In a method to form a pinch channel in a conventional device, for example, the perpendicular channels are separated by using the doping well of the different depths and concentrations. Nevertheless, this method shall control the implant energy and the thermal process accurately, which causes the difficulty of device reliability and repeatability. It is one of important goal to increase the electric reliability of the semiconductor device.

### SUMMARY

The disclosure is directed to a semiconductor structure and a method of manufacturing the same. The semiconductor structure comprises plural channel regions, and each of finger regions of the first well is sandwiched between two of the channel regions, thereby enhancing the pinch capability of the channel and decreasing the thermal effect of the device manufacturing process to make the electrical characteristics of the applied device more stable.

According to an aspect of the disclosure, a semiconductor structure includes a substrate having a first conductive type; a deep well having a second conductive type formed in the substrate and extending down from a surface of the substrate; a first well having the first conductive type formed in the deep well and extending down from the surface of the substrate; and a second well having the second conductive type formed in the deep well and extending down from the surface of the substrate, and the second well adjacent to the first well. The first well includes a block region and plural finger regions joined to one side of the block region, while the second well includes plural channel regions interlaced with the finger regions to separate the finger regions.

According to another aspect of the disclosure, a method of manufacturing semiconductor structure is provided. First, a substrate having a first conductive type is provided. A deep well having a second conductive type is formed in the substrate and extending down from a surface of the substrate. A first well having the first conductive type is formed in the deep well and extending down from the surface of the substrate, wherein the first well includes a block region and plural finger regions joined to one side of the block region. Also, a second well having the second conductive type is formed in the deep well and extending down from the surface of the substrate, and the second well is adjacent to the first well. The second well includes plural channel regions interlaced with the finger regions to separate the finger regions.

According to a further aspect of the disclosure, the semiconductor structure further comprises a first doping electrode region, a second doping electrode region and a third doping electrode region extending down from the surface of the substrate, the first and the third doping electrode regions formed within the block region of the first well and the first doping electrode region close to the finger regions, the second doping electrode region formed within the deep well and spaced apart from the first doping electrode region with a distance, wherein the first and the second doping electrode regions have the second conductive type, and the third doping electrode region has the first conductive type. During operation, the reverse bias could be applied on the first doping electrode region or the third doping electrode region to turn off the semiconductor structure.

### BRIEF DESCRIPTION OF THE DRAWINGS

FIG. 1A is top view of a semiconductor structure according to one embodiment of the disclosure.

FIG. 1B is a partial enlarging drawing of FIG. 1A.

FIG. 2 is a partial enlarging top view of another semiconductor structure according to the embodiment of the disclosure.

FIG. 3 is a cross-sectional view along the cross-sectional line AA′ of FIG. 2.

FIG. 4 is a cross-sectional view along the cross-sectional line BB′ of FIG. 2.

FIG. 5A and FIG. 5B respectively show an On-state and an Off-state of the semiconductor structure of the embodiment, while the semiconductor structure is turned off by supplying a reverse bias voltage such as −5V, −10V, −20V . . . to the P-type gate.

FIG. 6 is relationship between the drain current and the drain voltage at different applied gate voltages 0V, −5V, −10V, −15V, −18V, −20V, −22V, −25V and −30V.

FIG. 7A and FIG. 7B respectively show an On-state and an Off-state of the semiconductor structure of the embodiment, while the semiconductor structure is turned off by supplying a reverse bias voltage to the N-type source.

FIG. 8 is relationship between the drain current and the source voltage at different applied drain voltages.

FIG. 9A-FIG. 16B depict a process of manufacturing the semiconductor structure of the embodiment.

### DETAILED DESCRIPTION

The embodiment of the present disclosure provides a semiconductor structure and a method of manufacturing the same. The semiconductor structure of the embodiment is suitable for application of various semiconductor devices operated by different voltages, particularly the high voltage (HV) or ultra-HV semiconductor devices, such as HV or ultra-HV junction field effect transistor (JFET). The semiconductor structure of the embodiment comprises plural channel regions, and each of finger regions of the first well is sandwiched between two of the channel regions, thereby enhancing the pinch capability of the channel and decreasing the thermal effect of the device manufacturing process to make the electrical characteristics of the applied device more stable.

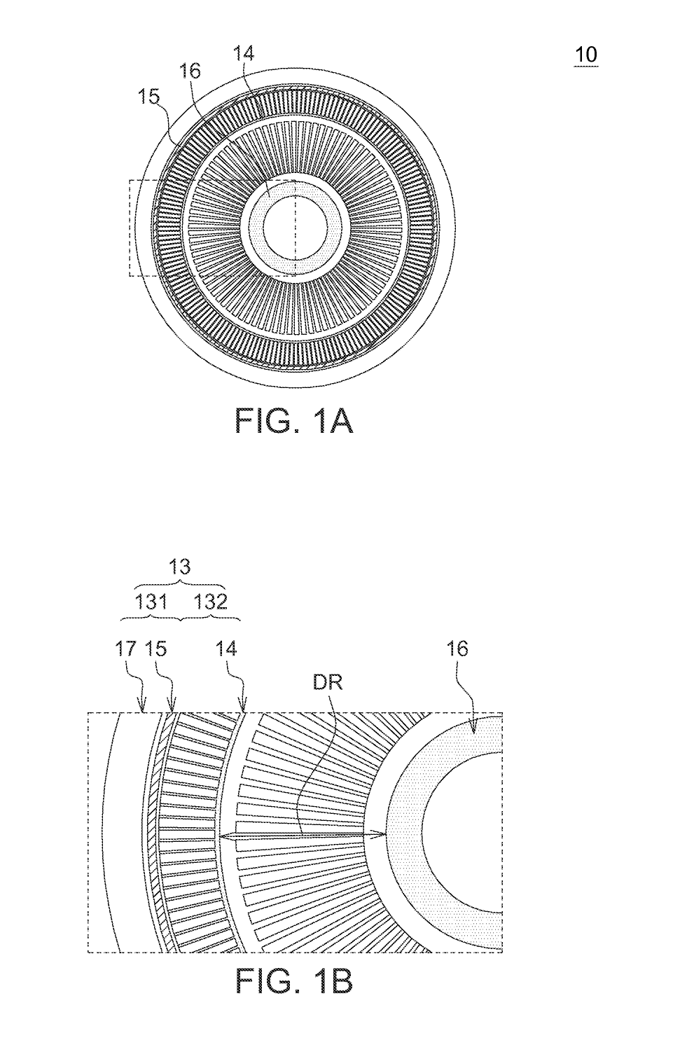

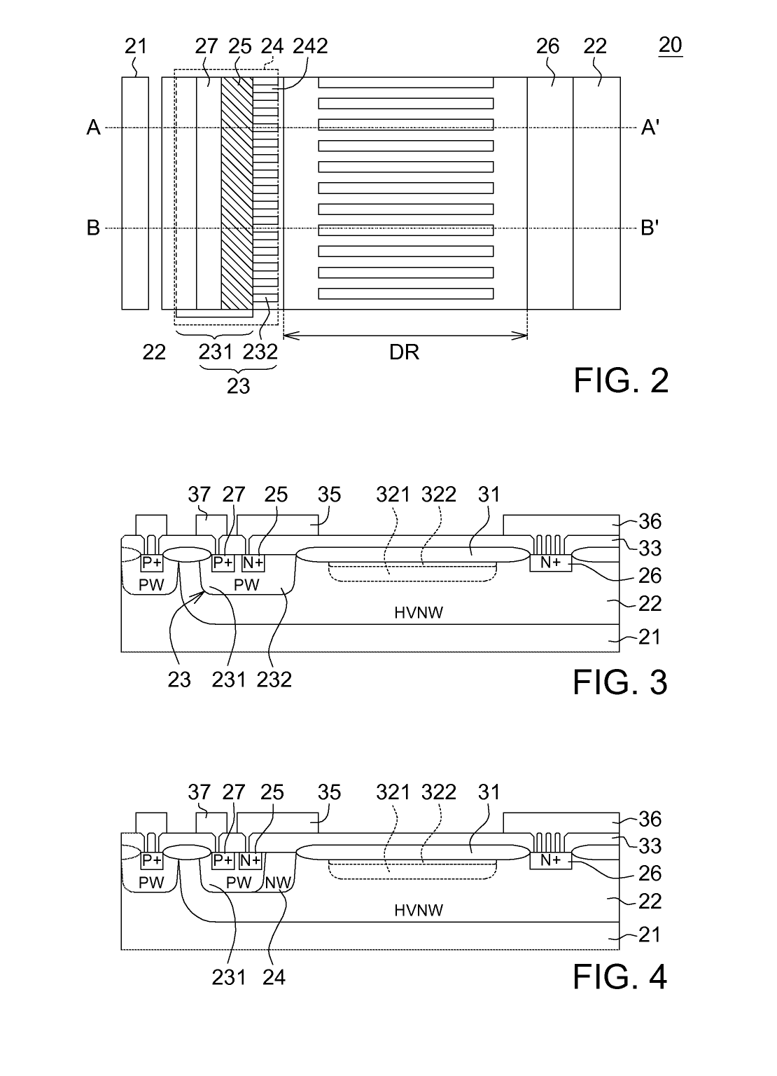

FIG. 1A is top view of a semiconductor structure according to one embodiment of the disclosure. FIG. 1B is a partial enlarging drawing of FIG. 1A. The semiconductor structure 10 of the embodiment comprises a first well 13 formed in a deep well of a substrate. The first well 13 includes a block region 131 and plural finger regions 132 joined to one side of the block region 131. A second well 14, having different conductive type from the first well, is adjacent to the first well 13 and includes plural channel regions (242 as shown in FIG. 2) interlaced with the finger regions 132 to separate the finger regions 132. The semiconductor structure 10 further comprises a first doping electrode region 15 (such as a source region) formed within the block region 131 of the first well 13, a second doping electrode region 16 (such as a drain region) formed within the deep well and spaced apart from the first doping electrode region 15 with a distance, and a third doping electrode region 17 (such as a gate region) formed within the block region 131 of the first well 13 and adjacent to the first doping electrode region 15. Also, the drift region DR between the second doping electrode region 16 and the second well 14 increase the breakdown voltage of the HV or ultra-HV semiconductor devices in applications.

FIG. 2 is a partial enlarging top view of another semiconductor structure according to the embodiment of the disclosure. FIG. 1A and FIG. 1B illustrate a semiconductor structure with the annular electrodes formed on the substrate. The invention is not limited to the annular electrodes, and other shapes (viewed from top) of electrodes could be constructed. For example, partial electrodes could be plural strips arranged in parallel, as shown in FIG. 2. FIG. 3 is a cross-sectional view along the cross-sectional line AA′ of FIG. 2. FIG. 4 is a cross-sectional view along the cross-sectional line BB′ of FIG. 2. Please refer to FIG. 2-FIG. 4 for illustrations of the embodiment.

The semiconductor structure 20 includes a substrate 21, a deep well 22 formed in the substrate 21 and extending down from the surface of the substrate 21, a first well 23 formed in the deep well 22 and extending down from the surface of the substrate 21, and a second well 24 formed in the deep well 22 and extending down from the surface of the substrate 21, wherein the second well 24 is adjacent to the first well 23. The first well 23 includes a block region 231 and plural finger regions 232 joined to one side of the block region 231, while the second well 24 includes plural channel regions 242 interlaced with the finger regions 232 to separate the finger regions 232. The substrate 21 and the first well have a first conductive type such as P type, while the deep well 22 and the second well 24 have a second conductive type such as N type. And vice versa.

In an embodiment, the first well 23 and the second well 24 extending down from the surface of the substrate 21 have the same depth substantially. In an embodiment, the finger regions 232/the channel regions 242 have the same width substantially, and the two adjacent finger regions 232 have the same interval substantially. However, the invention is not limited to the embodiment, and variations could be modified and adjusted according to the actual needs of the applications. For example, the widths and lengths of the channel regions 242, and the number of the finger regions 232 could be determined according to the applications.

The semiconductor structure 20 further comprises a first doping electrode region 25, a second doping electrode region 26 and a third doping electrode region 27. The first doping electrode region 25 (such as a source region), having the second conductive type, is extending down from the surface of the substrate 21 and formed within the block region 231 of the first well 23. The second doping electrode region 26 (such as a drain region), having the second conductive type, is extending down from the surface of the substrate 21 and formed within the deep well 22, wherein the second doping electrode region 26 is spaced apart from the first doping electrode region 25 with a distance. The third doping electrode region 27 (such as a gate region), having the first conductive type, is extending down from the surface of the substrate 21 and formed within the block region 231 of the first well 23.

As shown in FIG. 3 and FIG. 4, the drift region DR of the semiconductor structure 20 further comprises a dielectric 31 formed on the substrate 21 and positioned between the second doping electrode region 26 and the second well 24. The dielectric 31 could be a field oxide (FOX). In an embodiment, the semiconductor structure 20 further comprises a top region 321 and a grade region 322. The top region 321, having the first conductive type (such as P type, and the top region 321 also named as P-top), is formed in the deep well 22 and positioned beneath the dielectric 31. The grade region 322, having the second conductive type (such as N type, and the grade region 322 also named as N-grade), formed in the deep well 22 and positioned above the top region 321 and under the dielectric 31.

The semiconductor structure 20 comprises an inter-layered dielectric (ILD) 33 formed on the surface of the substrate 21 and exposing partial surfaces of the first doping electrode region 25, the second doping electrode region 26 and the third doping electrode region 27. The semiconductor structure 20 further comprises a first electrode 35, a second electrode 36 and a third electrode 37 formed on the ILD 33 and contacting said exposed partial surfaces of the first doping electrode region 25, the second doping electrode region 26 and the third doping electrode region 27, respectively.

The semiconductor structure of the embodiment has plural channel regions 242, and each of finger regions 232 having the first conductive type is sandwiched between two of the channel regions 242 having the second conductive type. In the application, the pinch-off voltage of the semiconductor device such as HV or Ultra-HV JFET is controlled by the channel width, and the pinch capability is influenced by channel length. Also, the conventional channel length of the UHV-JFET is formed by the depth of the well, which is seriously concerned with thermal effect or implant energy. The semiconductor device (such as HV(Ultra-HV) JFET) applied with the semiconductor structure of the embodiment increases the channel length, not only enhancing the pinch capability of the channel but also decreasing the thermal effect to make the electrical characteristics of the applied device more stable.

During operation of the semiconductor structure of the embodiment, a reverse bias could be applied to the first doping electrode region 25 (/first electrode 35, such as source) or the third doping electrode region 27 (/third electrode 37, such as gate) to enlarge the depletion region and increase the potential barrier, thereby turning off the semiconductor structure.

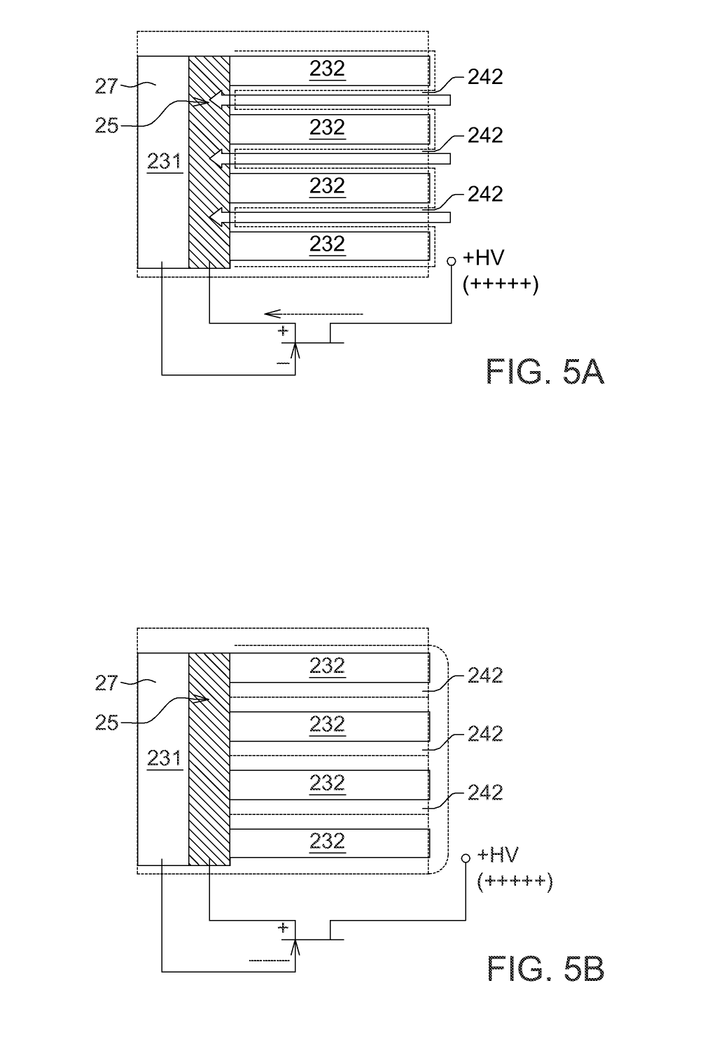

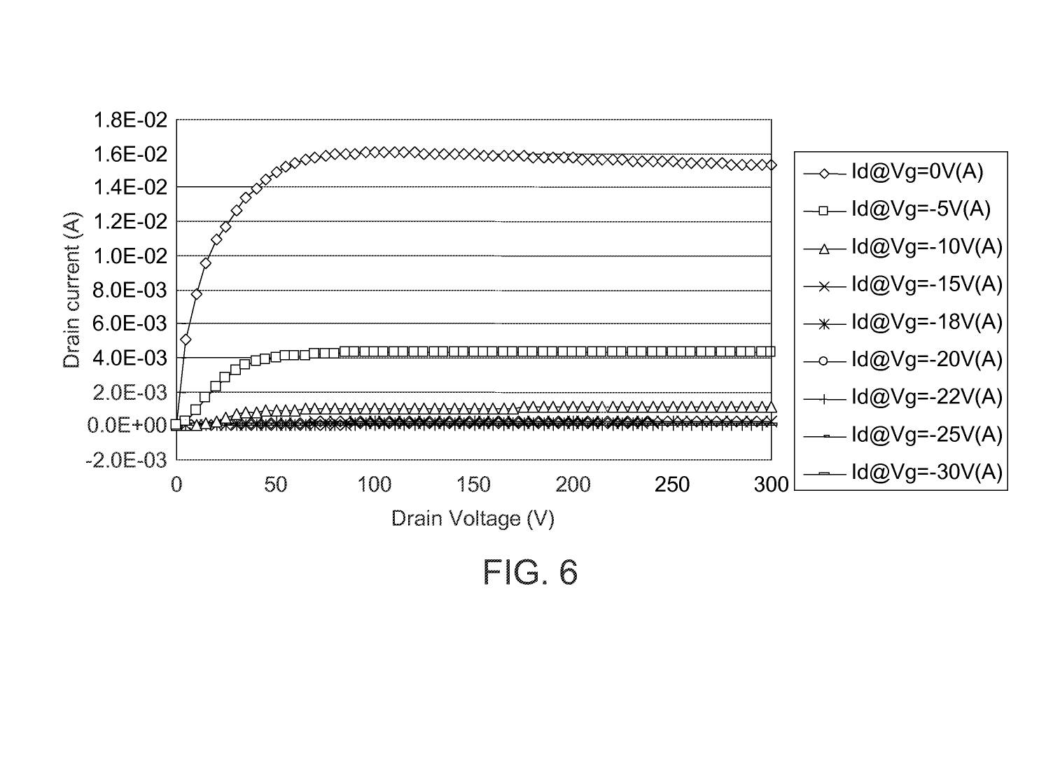

FIG. 5A and FIG. 5B respectively show an On-state and an Off-state of the semiconductor structure of the embodiment, while the semiconductor structure is turned off by supplying a reverse bias voltage such as −5V, −10V, −20V . . . to the P-type gate (ex: third doping electrode region 27/third electrode 37). FIG. 6 is relationship between the drain current and the drain voltage at different applied gate voltages 0V, −5V, −10V, −15V, −18V, −20V, −22V, −25V and −30V. As shown in FIG. 6, the measurement results show that the semiconductor structure is almost at the Off-state when the applied gate voltage reaches −10V.

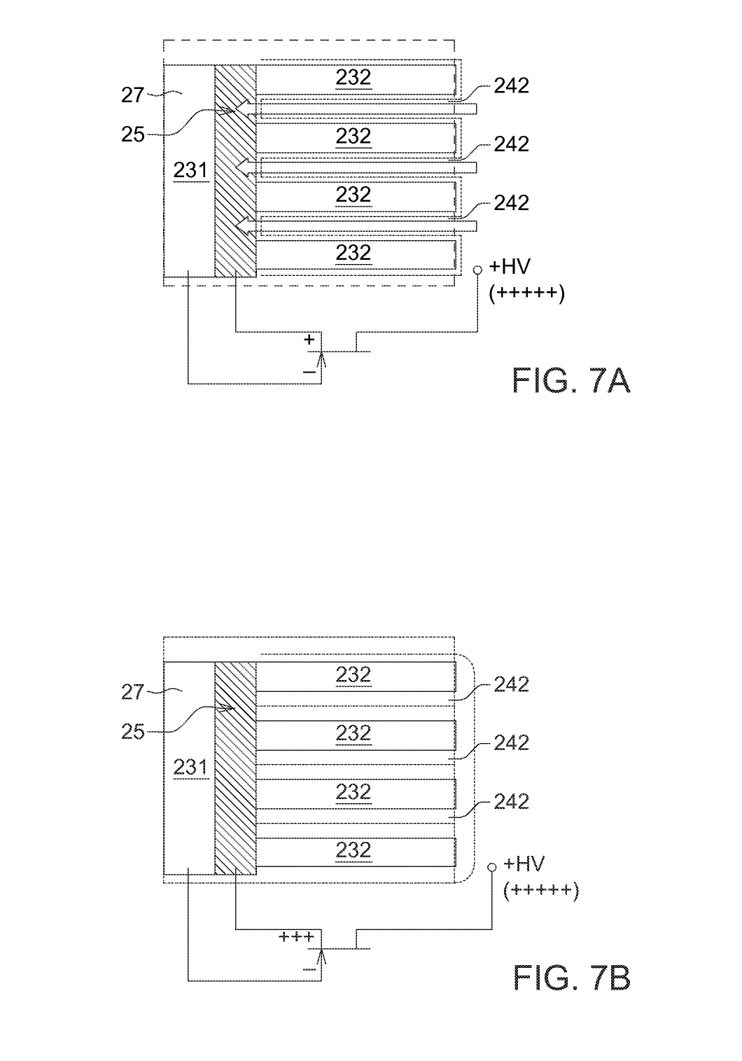

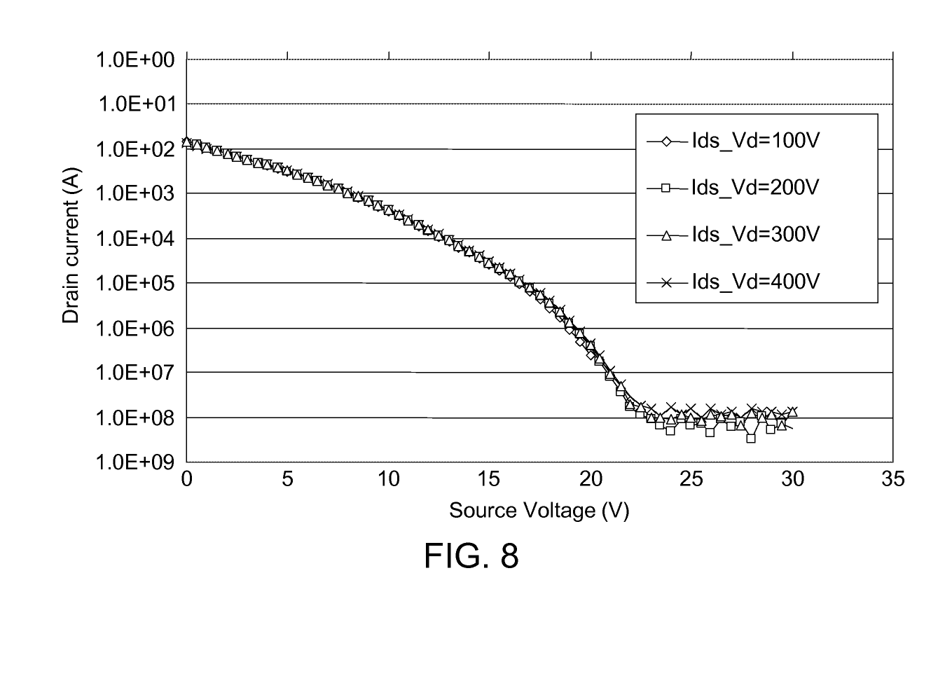

Alternatively, FIG. 7A and FIG. 7B respectively show an On-state and an Off-state of the semiconductor structure of the embodiment, while the semiconductor structure is turned off by supplying a reverse bias voltage such as 5V, 10V, 20V . . . to the N-type source (ex: first doping electrode region 25/first electrode 35). FIG. 8 is relationship between the drain current and the source voltage (ex: 0V, 5V, 10V . . . , 30V) at different applied drain voltages 100V, 200V, 300V and 400V. The measurement results show that the semiconductor structure can be turned off by applying a reverse bias voltage to source at different drain voltages.

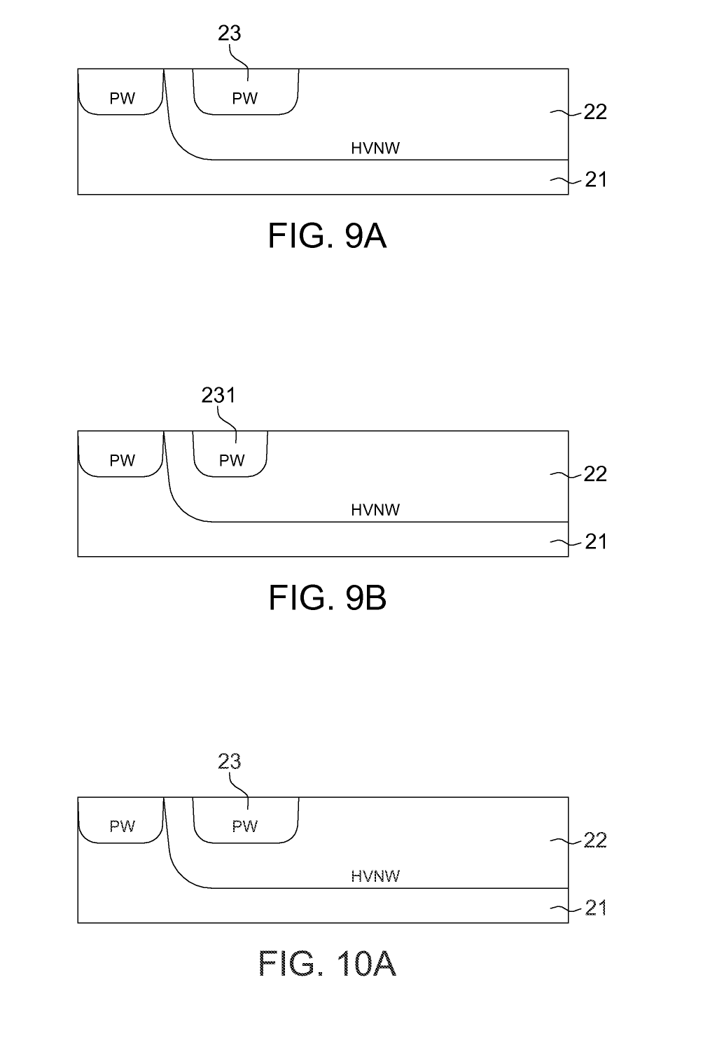

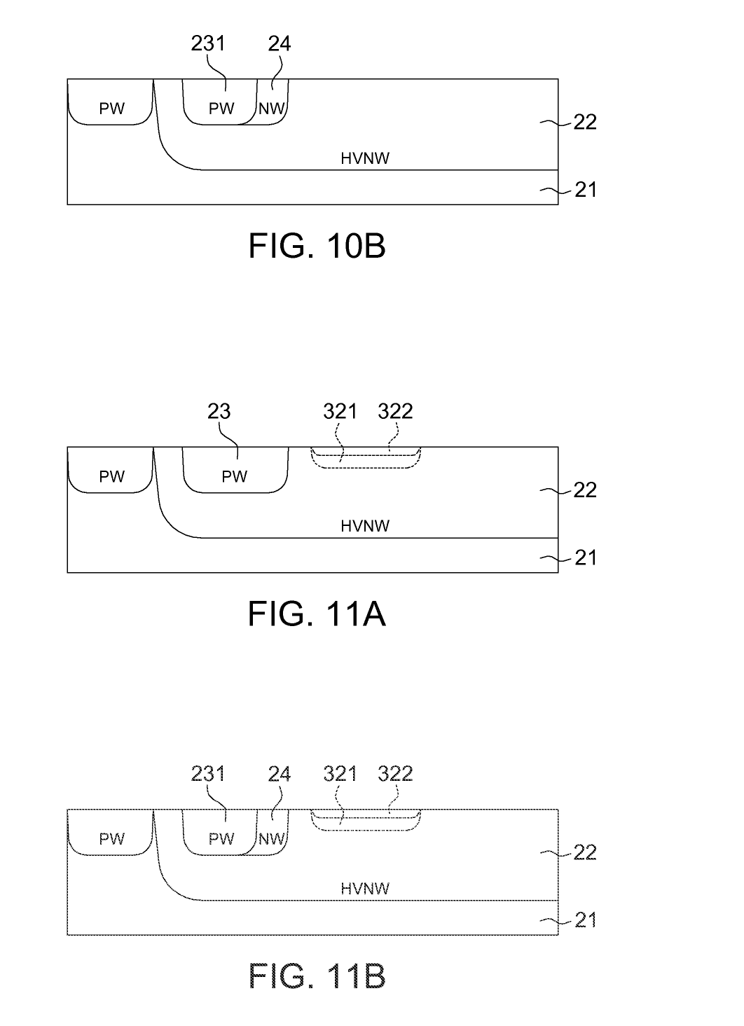

FIG. 9A-FIG. 16B depict a process of manufacturing the semiconductor structure of the embodiment. Figures labeled with A such as FIGS. 9A, 10A, 11A, . . . 16A illustrate a cross-sectional view along the cross-sectional line AA′ of FIG. 2, wherein the position of the cross-sectional line AA′ is corresponding to the block region 231 and the finger regions 232 of the first well 23. Figures labeled with B such as FIGS. 9B, 10 B, 11 B, . . . 16 B illustrate cross-sectional view along the cross-sectional line BB′ of FIG. 2, wherein the position of the cross-sectional line BB′ is corresponding to the block region 231 of the first well 23 and the channel regions 242 of the second well 24.

Also, P type and N type are selected as the first conductive type (i.e. conductive type of the substrate 21 and the first well 23) and the second conductive type (i.e. conductive type of the deep well 22 and the second well 24) for marking in the drawings. However, the invention is not limited thereto.

Please refer to FIG. 9A and FIG. 9B. First, a substrate 21 having a first conductive type (such as P type) is provided, and a deep well 22 having a second conductive type (such as N type) is formed in the substrate 21 by ion implant, and the deep well 22 extends down from the surface of the substrate 21. Next, a first well 23 having the first conductive type (such as P type) is formed in the deep well 22 and extending down from the surface of the substrate 21 by ion implant. The first well 23 includes a block region 231 and a plurality of finger regions 232 (FIG. 2) joined to one side of the block region 231. Also, other P-well (PW) could be formed outside the deep well 22.

Please refer to FIG. 10A and FIG. 10B. A second well 24 having the second conductive type (such as N type) is formed in the deep well 22 by ion implant, and the second well 24 extends down from the surface of the substrate 21 and adjacent to the first well 23. The second well 24 includes several channel regions 242 interlaced with the finger regions 232 to separate the finger regions 232 (FIG. 2).

In one embodiment, the drift region could include particular design for increasing the breakdown voltage of the applied semiconductor devices. Please refer to FIG. 11A and FIG. 11B. A top region 321 having the first conductive type (such as P type) is formed in the deep well by implant, and a grade region 322 having the second conductive type (such as N type) is formed on the top region 321.

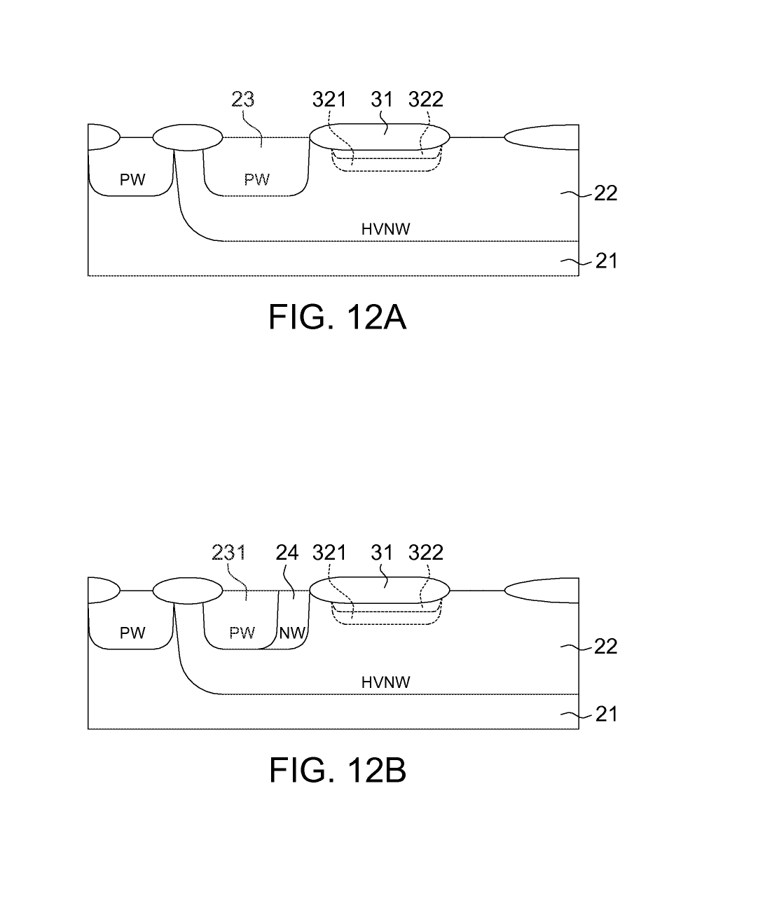

Please refer to FIG. 12A and FIG. 12B. A dielectric 31 such as filed oxide (FOX) is formed on the substrate 21 and positioned above the grade region 322. Examples of the dielectric 31 include FOX and shallow trench isolation (STI). FOX could be formed by photo-definition, etching and oxidation.

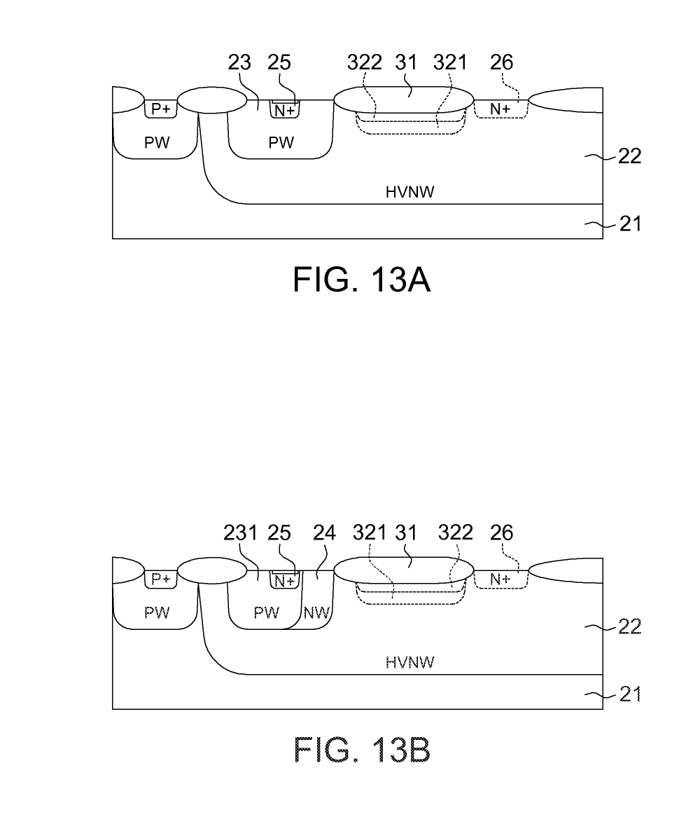

Please refer to FIG. 13A and FIG. 13B. A first doping electrode region 25 having the second conductive type (such as N type) is formed in the first well 23 (such as within the block region 231), and a second doping electrode region 26 having the second conductive type is simultaneously formed in the deep well 22 by ion implant. Both of the first doping electrode region 25 and the second doping electrode region 26 extend down from the surface of the substrate 21, and are spaced apart from each other by a distance. Also, position of the first doping electrode region 25 is adjacent to the finger regions 232 of the first well 23 (i.e. adjacent to the channel regions 242 of the second well 24).

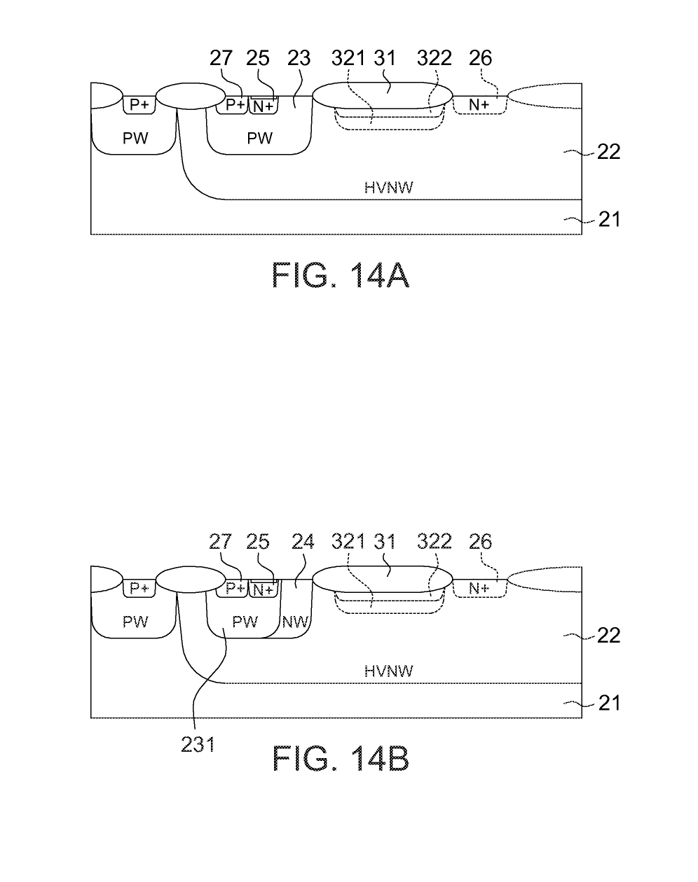

Please refer to FIG. 14A and FIG. 14B. A third doping electrode region 27 having the first conductive type (such as P type) is formed within the block region 231 of the first well 23 and extending down from the surface of the substrate 21 by ion implant.

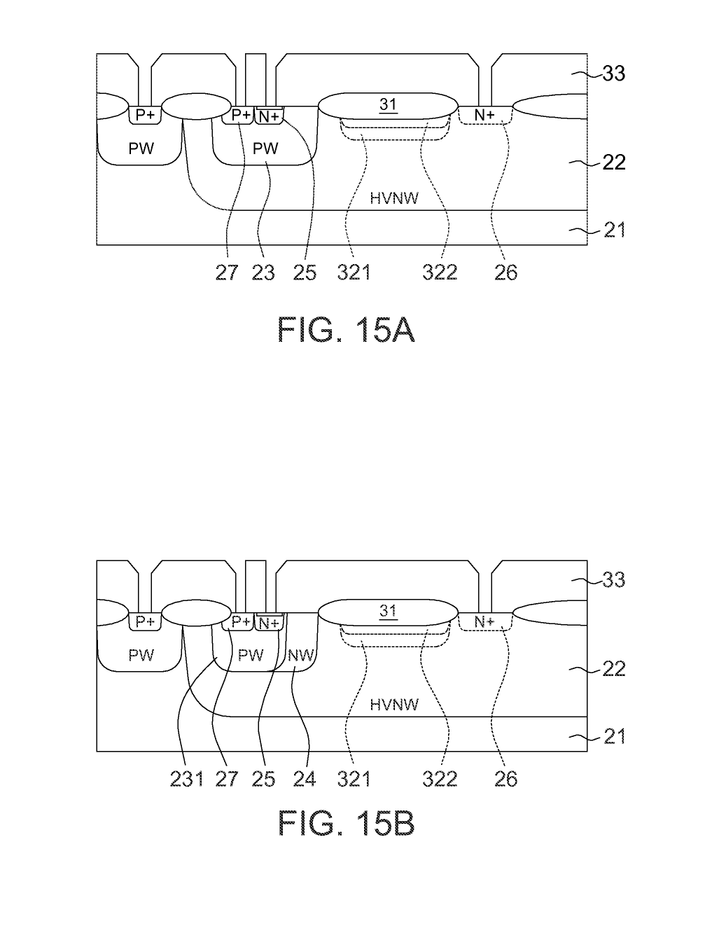

Please refer to FIG. 15A and FIG. 15B. By dielectric formation, pattern define and etching, an inter-layered dielectric (ILD) 33 is formed on the surface of the substrate 21 and exposes partial surfaces of the first doping electrode region 25, the second doping electrode region 26 and the third doping electrode region 27.

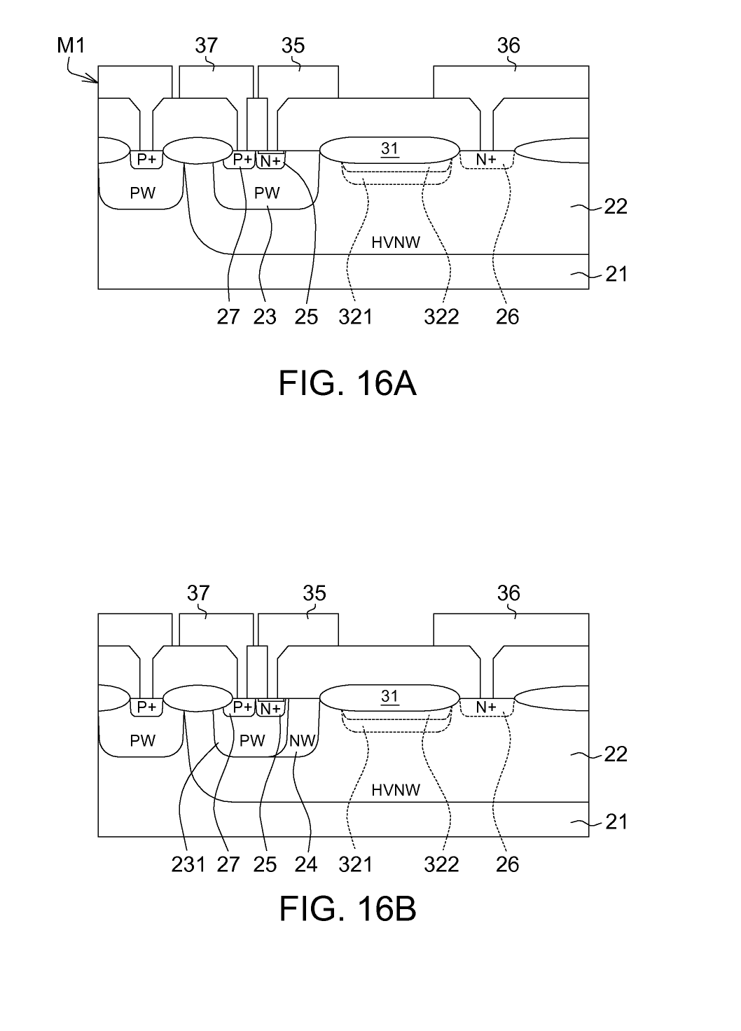

Please refer to FIG. 16A and FIG. 16B. A conductive layer (such as a first metal M1) is deposited on the substrate 21 and patterned by photo-define and etching, to form a first electrode 35, a second electrode 36 and a third electrode 37 on the ILD 33. The first electrode 35, the second electrode 36 and the third electrode 37, filling up the openings of the ILD 33, contact the exposed partial surfaces of the first doping electrode region 25, the second doping electrode region 26 and the third doping electrode region 27, respectively. The first electrode 35, the second electrode 36 and the third electrode 37 could function as source, drain and gate of the semiconductor device in the application. According to the embodiment, the channel length and width could be controlled and adjusted by layout pattern in the application, without changing the process.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor structure, comprising:
a substrate having a first conductive type;
a deep well having a second conductive type, extending down from a surface of the substrate and formed in the substrate;
a first well having the first conductive type, extending down from the surface of the substrate and formed in the deep well, the first well comprising:
a block region; and
a plurality of finger regions joined to one side of the block region; and
a second well having the second conductive type, extending down from the surface of the substrate and formed in the deep well and adjacent to the first well, the second well comprising a plurality of channel regions interlaced with the finger regions to separate the finger regions.

2. The semiconductor structure according to claim 1, further comprising:
a first doping electrode region having the second conductive type, extending down from the surface of the substrate and formed within the block region of the first well, wherein the first doping electrode region are close to the finger regions.

3. The semiconductor structure according to claim 2, further comprising:
a second doping electrode region having the second conductive type, extending down from the surface of the substrate and formed within the deep well, and the second doping electrode region being spaced apart from the first doping electrode region with a distance;
wherein the finger regions of the first well is positioned between the first doping electrode region and the second doping electrode region.

4. The semiconductor structure according to claim 3, further comprising:
a third doping electrode region having the first conductive type, extending down from the surface of the substrate and formed within the block region of the first well.

5. The semiconductor structure according to claim 4, further comprising:
an inter-layered dielectric (ILD) formed on the surface of the substrate and exposing partial surfaces of the first, second and third doping electrode regions.

6. The semiconductor structure according to claim 5, further comprising:
a first electrode, a second electrode and a third electrode, formed on the ILD and contacting said exposed partial surfaces of the first, second and third doping electrode regions, respectively.

7. The semiconductor structure according to claim 3, further comprising:
a dielectric formed on the substrate and positioned between the second doping electrode region and the second well.

8. The semiconductor structure according to claim 7, further comprising:
a top region having the first conductive type, formed in the deep well and positioned beneath the dielectric; and
a grade region having the second conductive type, formed in the deep well and positioned above the top region and under the dielectric.

9. The semiconductor structure according to claim 1, wherein the first well and the second well extending down from the surface of the substrate have the same depth substantially.

10. The semiconductor structure according to claim 1, wherein the finger regions have the same width substantially, and the two adjacent finger regions have the same interval substantially.

11. A method of manufacturing semiconductor structure, comprising:
providing a substrate having a first conductive type;
forming a deep well having a second conductive type in the substrate, and the deep well extending down from a surface of the substrate;
forming a first well having the first conductive type in the deep well, and the first well extending down from the surface of the substrate, the first well comprising a block region and a plurality of finger regions joined to one side of the block region; and
forming a second well having the second conductive type in the deep well, and the second well extending down from the surface of the substrate and adjacent to the first well, the second well comprising a plurality of channel regions interlaced with the finger regions to separate the finger regions.

12. The method according to claim 11, further comprising:
forming a first doping electrode region having the second conductive type within the block region of the first well, and the first doping electrode region extending down from the surface of the substrate and close to the finger regions.

13. The method according to claim 12, further comprising:
forming a second doping electrode region having the second conductive type within the deep well, and the second doping electrode region extending down from the surface of the substrate and being spaced apart from the first doping electrode region with a distance;
wherein the finger regions of the first well is positioned between the first doping electrode region and the second doping electrode region.

14. The method according to claim 13, further comprising:
forming a third doping electrode region having the first conductive type within the block region of the first well, and the third doping electrode region extending down from the surface of the substrate.

15. The method according to claim 14, further comprising:
forming an inter-layered dielectric (ILD) on the surface of the substrate, and the ILD exposing partial surfaces of the first, second and third doping electrode regions.

16. The method according to claim 15, further comprising:
forming a first electrode, a second electrode and a third electrode on the ILD, and contacting said exposed partial surfaces of the first, second and third doping electrode regions, respectively.

17. The method according to claim 13, further comprising:
forming a top region having the first conductive type in the deep well and positioned between the second doping electrode region and the second well; and
forming a grade region having the second conductive type in the deep well and positioned above the top region.

18. The method according to claim 17, further comprising:
forming a dielectric on the substrate and positioned above the grade region.

19. An operating method of semiconductor structure, comprising:
providing a semiconductor structure at least comprising:
a deep well having a second conductive type formed in a substrate and extending down from a surface of the substrate;
a first well having the first conductive type, extending down from the surface of the substrate and formed in the deep well, the first well comprising a block region and a plurality of finger regions joined to one side of the block region;
a second well having the second conductive type, extending down from the surface of the substrate and formed in the deep well and adjacent to the first well, the second well comprising a plurality of channel regions interlaced with the finger regions to separate the finger regions; and
a first doping electrode region, a second doping electrode region and a third doping electrode region extending down from the surface of the substrate, the first and the third doping electrode regions formed within the block region of the first well and the first doping electrode region close to the finger regions, the second doping electrode region formed within the deep well and spaced apart from the first doping electrode region with a distance, wherein the first and the second doping electrode regions have the second conductive type, and the third doping electrode region has the first conductive type;
applying a reverse bias on the first doping electrode region or the third doping electrode region to turn off the semiconductor structure.

20. The operating method according to claim 19, wherein the first doping electrode region is a source region, and the third doping electrode region is a gate region.
